(19) United States
(12) Patent Application Publication
(10) Pub. No.: US 2008/0094870 A1
(43) Pub. Date: Apr. 24, 2008

(54) Semiconductor memory device

(76) Inventors: Kazuki Tsujimura, Shiga (JP); Hiroaki Okuyama, Kyoto (JP)

Correspondence Address: MCDERMOTT WILL & EMERY LLP, 600 13TH STREET, NW, WASHINGTON, DC, 20005-3096, US

(21) Appl. No.: 11/976,239

(22) Filed: Oct. 23, 2007

(30) Foreign Application Priority Data
Oct. 24, 2006 (JP) 2006-288558

(51) Int. Cl. G11C 5/06; G11C 7/00; G11C 8/00

(52) U.S. Cl. 365/72; 365/189.011; 365/230.05

(57) ABSTRACT

A semiconductor memory device includes a memory cell array and peripheral control circuits. In each of the peripheral control circuits, a plurality of transistors are arranged at a substantially constant transistor pitch in a first direction which is the row direction or the column direction of the memory cell array. In the memory cell array, a memory cell length in the first direction is substantially n times the transistor pitch, wherein n is an integer.

### BACKGROUND OF THE INVENTION

1. Field of the Invention

The present invention relates to semiconductor memory devices, and particularly relates to a semiconductor memory device including a memory cell array and a peripheral control circuit.

2. Background Art

FIG. 7 shows a layout of a memory cell and a peripheral control circuit in a conventional semiconductor memory device. The transistor pitch in the peripheral control circuit is set constant in order to suppress variation in gate length of the transistors, as disclosed in Japanese Patent Application Laid Open Publication No. 9-289251, for example.

In FIG. 7, transistors 2, 2, . . . of a memory cell 1 are arrange perpendicularly to transistors 3, 3, . . . of the peripheral control circuit, and the cell width of the memory cell 1 is smaller than the width occupied by the transistors 3, 3, . . . arrange at a transistor pitch. When a memory cell array is formed by arranging a plurality of memory cells 1 and the peripheral control circuit is formed by arranging a plurality of transistors 3, 3, . . . perpendicularly to the transistors 2, 2, . . . of the memory cell 1, a transistor 3 enclosed by the two-dot chain line in FIG. 7 is arranged beyond the width of the memory cell 1.

### SUMMARY OF THE INVENTION

For example, in the semiconductor memory device shown in FIG. 7, since the cell width of the memory cell 1 is smaller than the width occupied by the transistors 3 arranged at the transistor pitch, when the transistors of the peripheral control circuit are arranged at a fixed transistor pitch for suppressing variation in gate length, a transistor arranged beyond the memory cell width (a transistor enclosed by the two-dot chain line in FIG. 7, for example) must be arrange in space other than that shown in FIG. 7. This inhibits the transistors of the peripheral control circuit from being arranged correspondingly to the memory cell array, so that additional space must be prepared for arranging the transistor beyond the memory cell width. This makes wasted space in the peripheral control circuit to increase the area of the peripheral control circuit.

In the present invention, the memory cell width is determined according to the transistor pitch in the peripheral control circuit. This permits the transistors of the peripheral control circuit to be arranged without making wasted space, thereby suppressing upsizing of the semiconductor memory device.

For example, a semiconductor memory device in accordance with a first aspect of the present invention includes a memory cell array and peripheral control circuits. In each peripheral control circuit, a plurality of transistors are arranged at a substantially constant transistor pitch in a first direction which is a row direction or a column direction of the memory cell array. While in the memory cell array, the memory cell length in the first direction is substantially n times the transistor pitch (n is an integer).

In the above semiconductor memory device, even when the transistors of the peripheral control circuits are arranged at a fixed transistor pitch for, for example, suppressing variation in gate length, the transistors thereof can be arranged without making wasted space because the memory cell width is substantially equal to an integral multiple of the transistor pitch of the transistors composing each peripheral control circuit.

A semiconductor memory device in accordance with a second aspect of the present invention includes a memory cell array and peripheral control circuits, similarly to the semiconductor memory device of the first aspect, wherein, in the memory cell array, the memory cell length in the first direction which several memory cells adjacent to each other in the first direction occupy is substantially n times the transistor pitch (n is an integer).

In the above semiconductor memory device, not only the transistors of the peripheral control circuits can be arranged without making wasted space but also the memory capacity can be increased or decreased in columns or rows, thereby facilitating layout change of the memory cell array.

A semiconductor memory device in accordance with a third aspect of the present invention includes not only a memory cell array and peripheral control circuits but also a plurality of control lines, wherein, in the memory cell array, the memory cell length in the first direction is substantially n times the wiring pitch of the control lines (n is an integer).

In the above semiconductor memory device, when the peripheral control circuits are arranged correspondingly to the memory cells arranged in an array, the control lines can be wired straight from the memory cell array to the peripheral control circuits. As a result, the length of the control lines can be shortened to a minimum, thereby suppressing unnecessary addition of a parasitic capacitance and/or a resistance to contemplate high-speed writing or reading operation.

A semiconductor memory device in accordance with a fourth aspect of the present invention includes not only a memory cell array and peripheral control circuits but also a plurality of bit lines and a plurality of word lines, wherein the memory cell length in the column direction of the memory cell array is substantially n times a first wiring pitch of the bit lines (n is an integer), and the memory cell length in the row direction of the memory cell array is substantially m times a second wiring pitch of the word lines (m is an integer).

In the above semiconductor memory device, when the peripheral control circuits are arranged correspondingly to the memory cells arranged in an array, the bit lines and the word lines can be wired straight from the memory cell array to the peripheral control circuits. As a result, the lengths of the bit lines and the word lines can be shortened to minimums, thereby suppressing unnecessary addition of a parasitic capacitance and/or a resistance to contemplate high-speed writing or reading operation.

### BRIEF DESCRIPTION OF THE DRAWINGS

FIG. 1A is a schematic circuit diagram of a semiconductor memory device in accordance with Embodiment 1.

FIG. 1B is a diagram showing an arrangement of transistors in the semiconductor memory device shown in FIG. 1A.

FIG. 2A is a schematic circuit diagram of a semiconductor memory device in accordance with Embodiment 2.

FIG. 2B is a diagram showing an arrangement of transistors in the semiconductor memory device shown in FIG. 2A.

FIG. 3A is a schematic circuit diagram of a semiconductor memory device in accordance with Embodiment 3.

FIG. 3B is a diagram showing an arrangement of transistors in the semiconductor memory device shown in FIG. 3A.

FIG. 4 is a diagram showing an arrangement of transistors in a semiconductor memory device in accordance with Embodiment 4.

FIG. 5 is a diagram showing an arrangement of transistors in a semiconductor memory device in accordance with Embodiment 5.

FIG. 6 is a diagram showing an arrangement of transistors in a semiconductor memory device in accordance with Embodiment 6.

FIG. 7 is a diagram showing an arrangement of transistors in a conventional semiconductor memory device.

### DETAILED DESCRIPTION OF PREFERRED EMBODIMENTS

Embodiments of the present invention will be described in detail with reference to the accompanying drawings. It should be noted that the present invention is not limited to the following embodiments.

### Embodiment 1

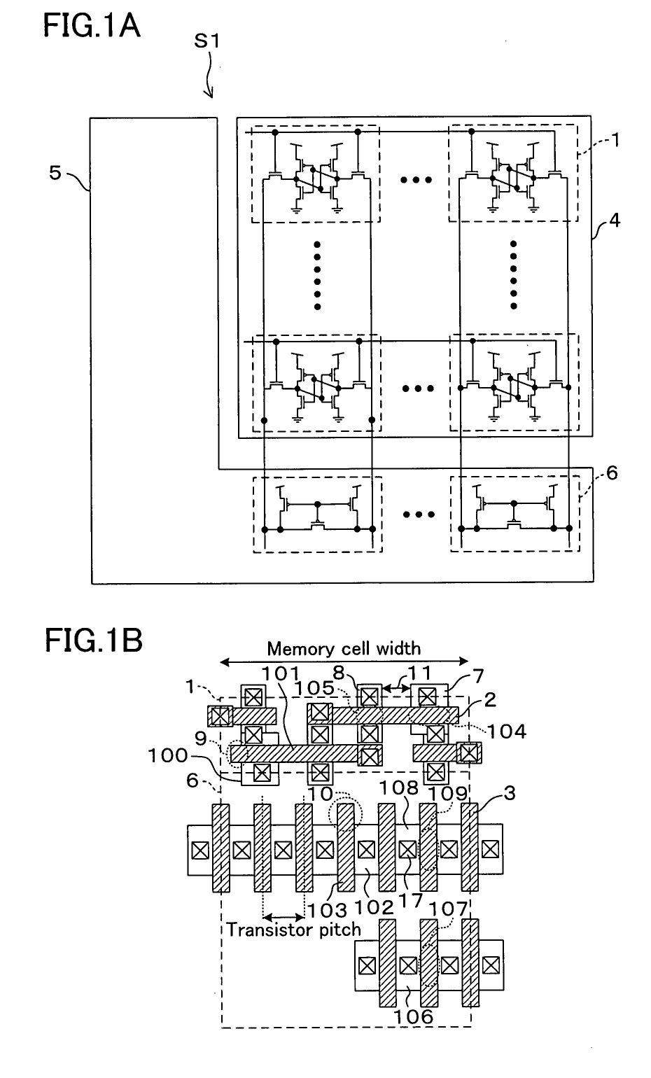

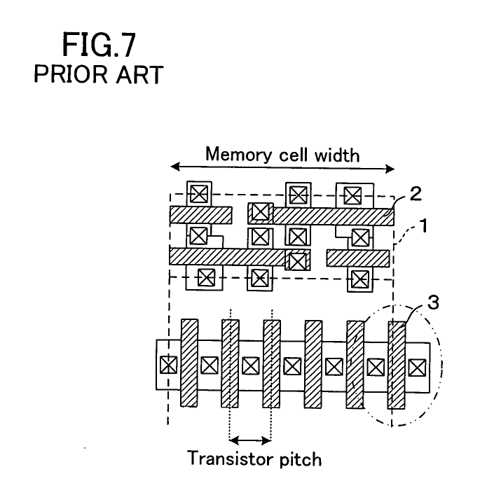

FIG. 1A is a schematic circuit diagram of a static random access memory (hereinafter referred to it as an SRAM) in Embodiment 1, and FIG. 1B is a diagram showing an arrangement of transistors 2, 2, . . . and transistors 3, 3, . . . composing the SRAM (S1). In FIG. 1A and FIG. 1B, the same reference numerals are assigned to the same elements as those in FIG. 7 for omitting description thereof.

In FIG. 1A, the SRAM (semiconductor memory device) (S1) is composed of a memory cell array 4 in which memory cells 1, 1, . . . are arranged in rows and columns, a control section 5, a plurality of bit lines, and a plurality of word lines. The drawings also show precharge circuits 6, 6, . . . connected to the bit lines, as one example of peripheral control circuits included in the control section 5. The peripheral control circuits control data reading or writing of the memory cells 1, 1, . . . .

In FIG. 1B, in each memory cell 1, a plurality of transistors 2, 2, . . . are arranged substantially in parallel with the word lines at a substantially constant transistor pitch in the row direction of the memory cell array 4 (the vertical direction in FIG. 1B). In each precharge circuit 6 of the control section 5, a plurality of transistors 3, 3, . . . are arranged substantially in parallel with the bit lines at a substantially constant transistor pitch in the column direction of the memory cell array 4 (the transverse direction in FIG. 1B). In other words, the transistors 2, 2, . . . of the memory cells 1, 1, . . . are arranged perpendicularly to the transistors 3, 3, . . . of the precharge circuits 6, 6, . . . . The transistor pitch in the memory cells 1, 1, . . . is shorter than the transistor pitch in the precharge circuits 6, 6, . . . .

The transistor pitch in the present description means intervals between the centers of gate electrodes of the transistors. For example, the transistor pitch in the precharge circuits 6, 6, . . . is a distance from the center of the gate electrode of a transistor 3 via a contact 17 to the center of the gate electrode of an adjacent transistor 3.

In each transistor 2 of the memory cells 1, 1, . . . , a first gate electrode 101 is protruded from a first diffusion region 100. As well, a second gate electrode 103 is protruded from a second diffusion region 102 in each transistor 3 of the precharge circuits 6, 6, . . . . The protrusion amount 9 of a part of the first gate electrode 101 which is protruded from the first diffusion region 100 in each memory cell 1 is smaller than the protrusion amount 10 of a part of the second gate electrode 103 which is protruded from the second diffusion region 102 in each precharge circuit 6.

Each memory cell 1 includes four N-channel transistor (first N-channel transistors) 104 and two P-channel transistors (first P-channel transistors) 105, wherein each of the N-channel transistors and the P-channel transistors includes a diffusion region. A diffusion region (a first N-channel diffusion region) 7 of each N-channel transistor is arranged apart form a diffusion region (a first P-channel diffusion region) 8 of each P-channel transistor. Each precharge circuit 6 includes, similarly to the memory cells 1, 1, . . . , an N-channel transistor (a second N-channel transistor) 107 and a P-channel transistor (a second P-channel transistor) 109, wherein a diffusion region (a second N-channel diffusion region) 106 of the N-channel transistor is arranged apart from a diffusion region (a second P-channel diffusion region) 108 of the P-channel transistor. The distance 11 between the diffusion region of the N-channel transistor and the diffusion region of the P-channel transistor in each memory cell 1 is smaller than the distance (not shown) therebetween in each precharge circuit 6.

Further, each memory cell 1 is designed so that the cell width in the column direction of the memory cell array 4 (“memory cell width” in FIG. 1B) is substantially n times the transistor pitch in the precharge circuits 6, 6, . . . wherein n is an integer.

As described above, in the present embodiment, the cell width of each memory cell 1 in the column direction is substantially equal to an integer multiple of the transistor pitch of the transistors 3, 3, . . . composing the precharge circuits 6. Accordingly, even when the transistors 3, 3, . . . composing the precharge circuits 6, 6, . . . are arranged at a fixed transistor pitch for, for example, suppressing variation in gate length, the transistors 3, 3, . . . can be arranged correspondingly to the memory cell array 4 without making wasted space. This leads to suppression of upsizing of the SRAM (S1).

Further, when the transistor pitch in the memory cells 1, 1, . . . is set shorter than the transistor pitch in the precharge circuits 6, 6, . . . upsizing of the memory cell array 4 can be suppressed.

As to the protrusion amounts of the gate electrodes and the distances between the diffusion regions of the N-channel transistors and the diffusion regions of the P-channel transistors, these physical amounts in each memory cell 1 are set smaller than those in each precharge circuit 6. This leads to an increase in gate width of the transistors 2, 2, . . . ensuring operation characteristics of the memory cells 1, 1, . . . .

In addition, when the gate electrodes are arranged in parallel with each other and the transistor pitch is set substantially constant in each memory cell 1, the manufacturing yield of the SRAM (S1) increases.

It is noted that though the precharge circuits 6, 6, . . . are referred to as an example of the peripheral control circuits included in the control section 5, the control section 5 may be composed of any of sense amplifier circuits, column selection circuit, and data write circuits (not shown).

### Embodiment 2

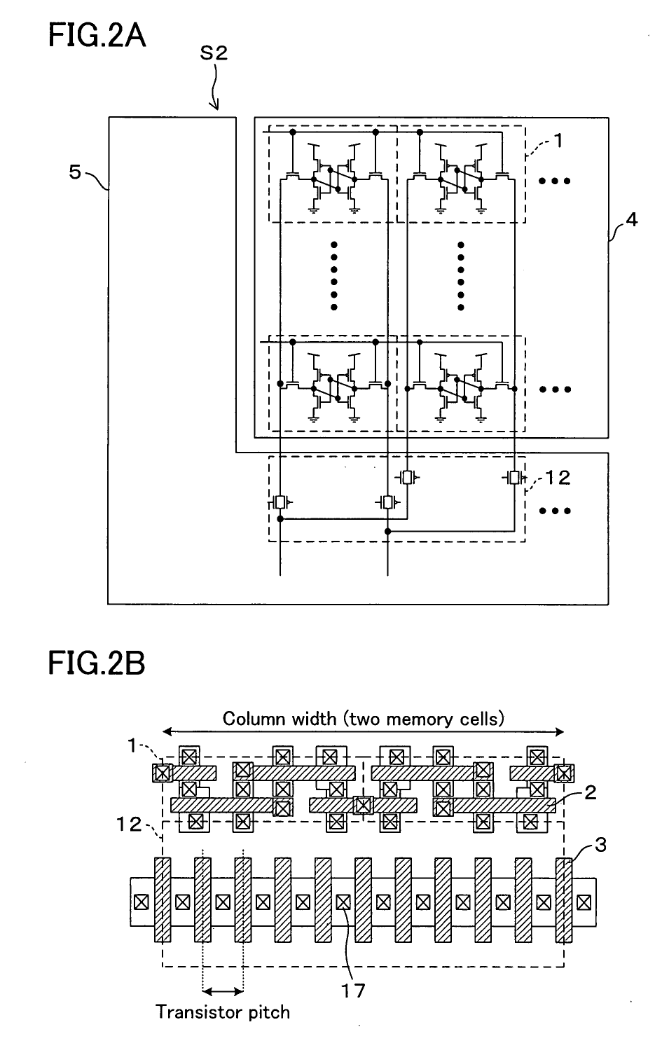

FIG. 2A is a schematic circuit diagram of a SRAM (S2) in accordance with Embodiment 2, and FIG. 2B is a diagram showing an arrangement of transistors 2, 2, . . . and transistors 3, 3, . . . composing an SRAM (S2). In FIG. 2A and FIG. 2B, the same reference numerals are assigned to the same elements as those in FIG. 1 for omitting description thereof.

As shown in FIG. 2A, in the present embodiment, column selection circuits 12, 12, . . . (for two columns) are referred to as one example of the peripheral control circuits included in the control section 5.

Further, as shown in FIG. 2B, a plurality of transistors 3, 3, . . . are provided in each column selection circuit 12, wherein each transistor 3 is arranged so as to extend substantially in parallel with the bit lines at a substantially constant transistor pitch in the column direction of the memory cell array 4.

The memory cells 1, 1, . . . in the present embodiment are designed so that the width that several memory cells 1, 1, . . . (two memory cells 2 in this case) arranged adjacent to each other in the column direction of the memory cell array 4 occupy is substantially equal to n times the transistor pitch of the transistors 3, 3, . . . of the column selection circuits 12, 12, . . . , wherein n is an integer.

As described above, in addition to the effects obtained in Embodiment 1, the present embodiment obtains an effect that the memory capacity can be increased or decreased in columns, achieving easy layout change of the memory cell array.

### Embodiment 3

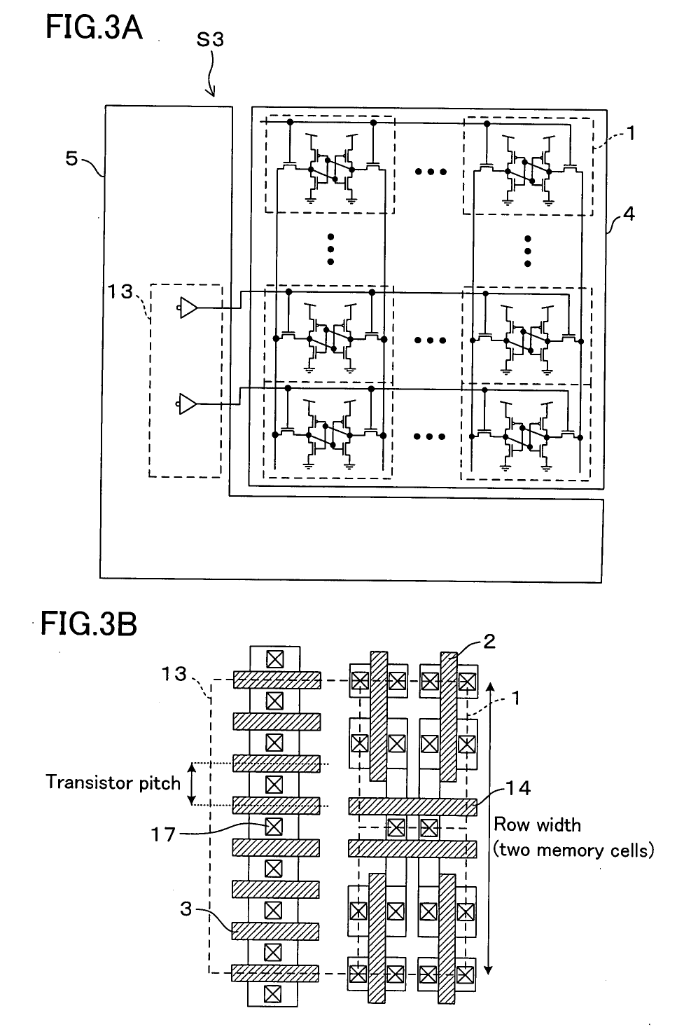

FIG. 3A is a schematic circuit diagram of a SRAM (S3) in accordance with Embodiment 3, and FIG. 3B is a diagram showing an arrangement of transistors 2, 2, . . . and transistors 3, 3, . . . composing an SRAM (S3). In FIG. 3A and FIG. 3B, the same reference numerals are assigned to the same elements as those in FIG. 1 for omitting description thereof.

As shown in FIG. 3A, in the present embodiment, word line drive circuits 13, 13 . . . are referred to as one example of the peripheral control circuits included in the control section 5.

As further shown in FIG. 3B, six transistors are provided in each memory cell 1, wherein two of the six are N-channel transistors 14, 14 while the other four are P-channel transistors. Each of the N-channel transistors and the P-channel transistors includes a gate electrode. Each gate electrode of the N-channel transistors 14, 14 is arranged substantially in parallel with the word lines while each gate electrode of the P-channel transistors is arranged substantially in parallel with the bit lines. In other words, each gate electrode of the N-channel transistors 14, 14 is arranged perpendicular to each gate electrode of the P-channel transistors.

The memory cells 1, 1, . . . in the present embodiment are designed so that the width that several memory cells 1 (two memory cells in this case) arranged adjacent to each other in the row direction of the memory cell array 4 occupy is substantially equal to n times the transistor pitch of the transistors 3, 3, . . . of the word line drive circuits 13, 13, . . . , wherein n is an integer.

As described above, in addition to the effects obtained in Embodiment 1, the present embodiment obtains an effect that the memory capacity can be increased or decreased in rows, achieving easy layout change of the memory cell array.

Further, each gate electrode of the N-channel transistors 14, 14 is arranged perpendicular to each gate electrode of the P-channel transistors in each memory cell 1. This means only one boundary formed between the N-channel transistors 14 and the P-channel transistors in each memory cell 1, leading to reduction in area where the memory cell array 4 occupies in the semiconductor memory device.

It is noted that though the word line drive circuits 13, 13, . . . are referred to as one example of the peripheral control circuits included in the control section 5, the control section 5 may include row decoder circuits (not shown).

### Embodiment 4

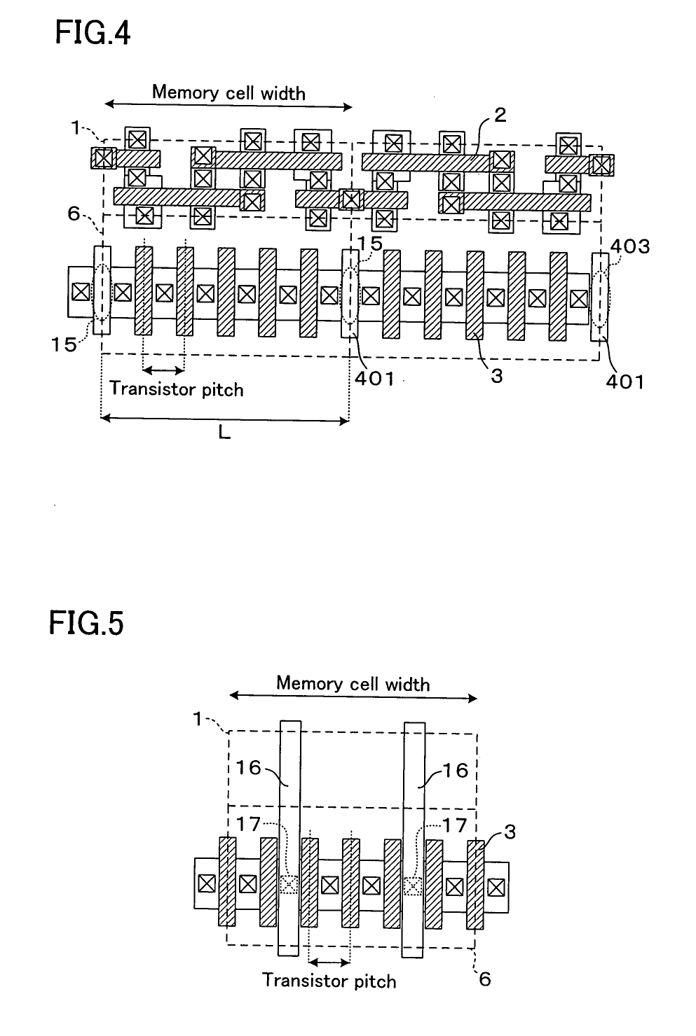

FIG. 4 is a diagram showing an arrangement of transistors composing an SRAM in accordance with Embodiment 4. In FIG. 4, the same reference numerals are assigned to the same elements as those in FIG. 1 for omitting description thereof.

As shown in FIG. 4, in the present embodiment, the precharge circuits 6, 6, . . . in Embodiment 1 are referred to as one example of the peripheral control circuits included in the control section 5. In each precharge circuit 6, a plurality of transistors 3, 3, . . . are arranged similarly to those in Embodiment 1, wherein a dummy transistor is arranged at each end of the precharge circuits 6, 6, . . . . In other words, the dummy transistor is interposed between adjacent precharge circuits 6 and 6 substantially in parallel with the transistors 3, 3, . . . of the precharge circuits 6, 6, . . . . The dummy transistor may be an inactive transistor 15 including a gate electrode 401 and a diffusion region 402 or an inactive transistor 403 including only a gate electrode 401.

The memory cells 1, 1, . . . are designed so that the cell width thereof in the row direction of the memory cell array 4 is substantially equal to the distance between adjacent dummy transistors 15 and 15. Herein, the distance between the adjacent dummy transistors is denoted by L in FIG. 4 and means a distance between the center of the gate electrode of a dummy transistor and the center of the gate electrode of an adjacent dummy transistor. When the memory cells 1, 1, . . . are arranged and the precharge circuits 6, 6, . . . are arranged so as to correspond thereto for manufacturing a semiconductor memory device, the dummy transistor (dummy transistor 15 or dummy transistor 403) is arranged along each boundary between adjacent memory cells 1, 1, . . . .

As described above, in addition to the effect obtained in Embodiment 1, the present embodiment obtains effects that: even in the case where the dummy transistors are arranged for, for example, suppressing variation in gate length, there is no need to prepare additional space for arranging the dummy transistors; and an SRAM can be formed without making wasted space only by arranging the precharge circuits 6, 6, . . . so as to correspond to the memory cells 1, 1, . . . . Hence, upsizing of the semiconductor memory device can be suppressed.

It is noted that the distance (L) between adjacent dummy transistors may be substantially equal to the length in the row direction which several memory cells arranged adjacent to each other in the row direction occupy or may be equal to the length in the column direction which several memory cells arranged adjacent to each other in the column direction occupy.

### Embodiment 5

FIG. 5 is a diagram showing an arrangement of transistors composing an SRAM in accordance with Embodiment 5. In FIG. 5, the same reference numerals are assigned to the same elements as those in FIG. 1 for omitting description thereof.

As shown in FIG. 5, in the present embodiment, the precharge circuits 6, 6, . . . in Embodiment 1 are referred to as one example of the peripheral control circuits included in the control section 5. In each precharge circuit 6, a plurality of transistors 3, 3, . . . are arranged in the column direction of the memory cell array 4 at a constant transistor pitch so as to extend in the row direction of the memory cell array 4. A contact 17 is formed between adjacent transistors 3 and 3. A plurality (two in FIG. 5) of bit lines 16, 16, . . . are connected to the memory cells 1, 1, . . . and are wired in the row direction of the memory cell array 4 so that the centers thereof agree with the centers of the corresponding contacts 17, 17, . . . .

As described above, in addition to the effects obtained in Embodiment 1, the present embodiment obtains an effect that the bit lines 16, 16, . . . connected to the memory cell array 4 can be wired straight even in the peripheral control circuit 5. Accordingly, when the bit lines 16, 16, . . . are wired from the memory cells 1, 1, . . . to sense amplifier circuits (not shown, one example of the peripheral control circuits), the wiring length thereof is shortened to a minimum, suppressing addition of unnecessary parasitic capacity and/or resistance. Hence, high speed reading operation is contemplated.

### Embodiment 6

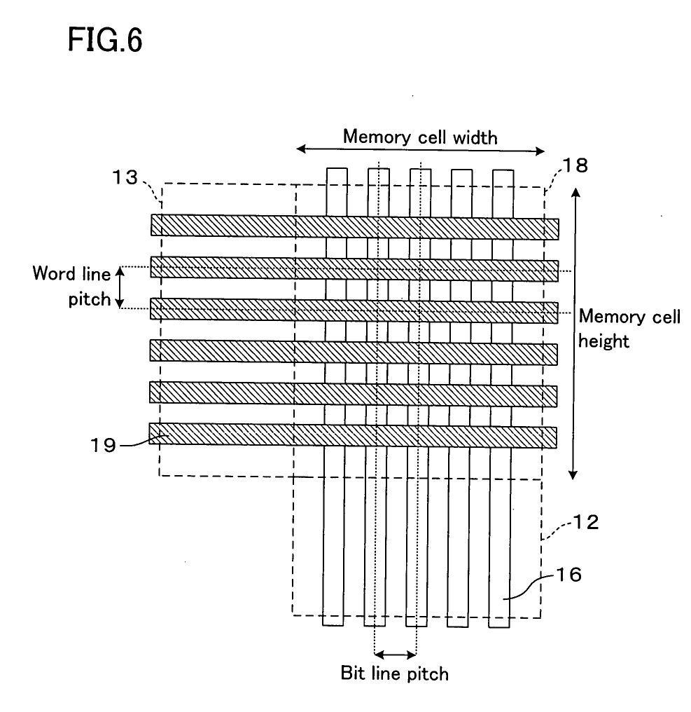

FIG. 6 is a diagram showing an arrangement of transistors composing an SRAM in accordance with Embodiment 6. In FIG. 6, the same reference numerals are assigned to the same elements as those in FIG. 1 for omitting description thereof.

As shown in FIG. 6, each memory cell in the present embodiment is a multi-port memory cell 18. The multi-port memory cell 18 means a memory cell capable of being connected to a plurality of bit lines 16, 16, . . . and a plurality of word lines 19, 19, . . . . Column selection circuits 12, 12, . . . and word line drive circuits 13, 13, . . . are referred to as one example of the peripheral control circuits included in the control section 5.

The plurality of bit lines 16, 16, . . . are arranged in parallel with each other at a constant bit line pitch (a first wiring pitch). The bit line pitch means, as shown in FIG. 6, a distance between the centers of adjacent bit lines 16 and 16. The plurality of word lines 19, 19, . . . are arranged in parallel with each other and substantially perpendicularly to the bit lines 16, 16, . . . at a constant word line pitch (a second wiring pitch). The word line pitch means, as shown in FIG. 6, a distance between the centers of adjacent word lines 19 and 19. Each multi-port memory cell 8 is designed so that the length (memory cell width in FIG. 6) thereof in the row direction of the memory cell array 4 is substantially equal to n times the bit line pitch (n is an integer) and the length (memory cell height in FIG. 6) thereof in the column direction of the memory cell array 4 is substantially equal to m times the word line pitch (m is an integer).

As described above, in the present embodiment, the cell width of each multi-port memory cells 18 is substantially equal to an integer multiple of the pitch of the bit lines 16 and the cell height of each multi-port memory cells 18, 18, . . . is substantially equal to an integer multiple of the pitch of the word lines 19, 19, . . . . Accordingly, when the multi-port memory cells 18, 18, . . . are arranged in an array and the column selection circuit 12 and the word line drive circuit 13 as the peripheral control circuits are arranged so as to correspond to the multi-port memory cells 18, 18, . . . for forming an SRAM, the bit lines 16, 16, . . . and the word lines 19, 19, . . . can be wired straight from the memory cell array 4 to the control section 5. This shortens the lengths of the bit lines 16, 16, . . . and the word lines 19, 19, . . . to minimums, suppressing addition of unnecessary parasitic capacity and/or resistance. Hence, high speed writing or reading operation is contemplated.

Though the multi-port memory cells 18 are connected to the plurality of bit lines 16, 16, . . . and the plurality of word lines 19, 19, . . . in the present embodiment, but may be connected to only the plurality of bit lines 16, 16, . . . or only the plurality of word lines 19, 19 . . . .

What is claimed is:

1. A semiconductor memory device comprising:
a memory cell array formed of a plurality of memory cells arranged in matrix; and
peripheral control circuits each including a plurality of transistors for controlling data reading or writing of the memory cells, the plurality of transistors being arranged in a first direction, which is one of a row direction and a column direction of the memory cell array, at a substantially constant transistor pitch,
wherein each of the memory cells is designed so that a length thereof in the first direction is substantially n times the transistor pitch (n is an integer).

2. A semiconductor memory device comprising:
a memory cell array formed of a plurality of memory cells arranged in matrix; and
peripheral control circuits each including a plurality of transistors for controlling data reading or writing of the memory cells, the plurality of transistors being arranged in a first direction, which is one of a row direction and a column direction of the memory cell array, at a substantially constant transistor pitch,
wherein the memory cells are designed so that a length in the first direction, which several memory cells arranged adjacent to each other in the first direction occupy, is substantially n times the transistor pitch (n is an integer).

3. The semiconductor memory device of claim 1,
wherein each of the memory cells includes a transistor,
the transistor of each of the memory cells is arranged substantially perpendicular to the transistors of the peripheral control circuits.

4. The semiconductor memory device of claim 1,
wherein each of the memory cells includes a plurality of transistors arranged at a substantially constant transistor pitch, and
the transistor pitch in the memory cells is shorter than the transistor pitch in the peripheral control circuits.

5. The semiconductor memory device of claim 1,
wherein a dummy transistor is arranged substantially in parallel with the transistors of the peripheral control circuits between adjacent peripheral control circuits.

6. The semiconductor memory device of claim 1,
wherein a dummy transistor is arranged substantially in parallel with the transistors of the peripheral control circuits at each end of the peripheral control circuits.

7. The semiconductor memory device of claim 5,
wherein the dummy transistor is an inactive transistor including a gate electrode and a diffusion region.

8. The semiconductor memory device of claim 5,
wherein the dummy transistor is an inactive transistor including a gate electrode.

9. The semiconductor memory device of claim 1, further comprising:
contacts formed between adjacent transistors of the peripheral control circuits; and
bit lines connected to the memory cells along a row direction of the memory cell array, the bit lines being wired through the centers of the contacts,
wherein the first direction is a column direction of the memory cell array.

10. The semiconductor memory device of claim 1,
wherein the first direction is a column direction of the memory cell array,
each of the memory cells includes a plurality of transistors each including a gate electrode, and
the transistors of the memory cells are arranged so that the gate electrodes are arranged in parallel with each other.

11. The semiconductor memory device of claim 1,
wherein the first direction is a row direction of the memory cell array,
each of the memory cells includes a plurality of transistors each including a gate electrode,
two transistors of the plurality of transistors of each of the memory cells are arranged so that the gate electrodes thereof are arranged in parallel with each other while the other transistors thereof are arranged so that gate electrodes thereof are arranged in parallel with each other and perpendicularly to the gate electrodes of the two transistors.

12. A semiconductor memory device, comprising:
a memory cell array formed of a plurality of memory cells arranged in matrix;
peripheral control circuits for controlling data reading or data writing of the memory cells, and
a plurality of control lines arranged in a first direction, which is a row direction or a column direction of the memory cell array, at a substantially constant wiring pitch,
wherein each of the memory cells is designed so that a length thereof in the first direction is substantially n times the wiring pitch (n is an integer).

13. A semiconductor memory device, comprising:
a memory cell array formed of a plurality of memory cells arranged in matrix;
peripheral control circuits for controlling data reading or data writing of the memory cells:
a plurality of bit lines arranged in a column direction of the memory cell array at a substantially constant first wiring pitch; and
a plurality of word lines arranged in a row direction of the memory cell array at a substantially constant second wiring pitch,
wherein each of the memory cells is designed so that a length thereof in the column direction of the memory cell array is substantially n times the first wiring pitch (n is an integer) and a length thereof in the row direction of the memory cell array is substantially m times the second wiring pitch (m is an integer).

14. The semiconductor memory device of claim 12,
wherein the memory cells are multi-port memory cells connected to the plurality of control lines.

15. The semiconductor memory device of claim 13,
wherein the memory cells are multi-port memory cells connected to the plurality of bit lines and the plurality of word liens.

16. The semiconductor memory device of claim 1,
wherein each of the memory cells includes a transistor including a first diffusion region and a first gate electrode protruded from the first diffusion region,
each of the peripheral control circuits includes a transistor including a second diffusion region and a second gate electrode protruded from the second diffusion region, and
the first gate electrode is protruded from the first diffusion region shorter than the second gate electrode protruded from the second diffusion region.

17. The semiconductor memory device of claim 1,
wherein each of the memory cells includes a first N-channel transistor including a first N-channel diffusion region and a first P-channel transistor including a first P-channel diffusion region and arranged apart from the first N-channel transistor,
each of the peripheral control circuit includes a second N-channel transistor including a second N-channel diffusion region and a second P-channel transistor including a second P-channel diffusion region and arranged apart from the second N-channel transistor, and
a distance between the first N-channel diffusion region and the first P-channel diffusion region is smaller than a distance between the second N-channel diffusion region and the second P-channel diffusion region.

18. The semiconductor memory device of claim 1,
wherein the first direction is a column direction of the memory cell array, and
the peripheral control circuits are any of bit line precharge circuits, sense amplifier circuits, column selection circuits, and data write circuits.

19. The semiconductor memory device of claim 1,
wherein the first direction is a row direction of the memory cell array, and
the peripheral control circuits are word line drive circuits or row decoder circuits.

20. The semiconductor memory device of claim 1, which is an SRAM.

21. The semiconductor memory device of claim 1,
wherein each of the memory cells includes six transistors, four of them being N-channel transistors while the other two being P-channel transistors.
